(19) United States
(12) Patent Application Publication
(10) Pub. No.: US 2015/0372197 A1
(43) Pub. Date: Dec. 24, 2015

(54) LIGHT-EMITTING DIODE ILLUMINATION APPARATUS

(71) Applicant: YAZAKI CORPORATION, Tokyo (JP)

(72) Inventor: Takayuki IKEDA, Shizuoka (JP)

(21) Appl. No.: 14/842,132

(22) Filed: Sep. 1, 2015

Related U.S. Application Data
(63) Continuation of application No. PCT/JP2014/055078, filed on Feb. 28, 2014.

(30) Foreign Application Priority Data
Mar. 5, 2013 (JP) 2013-042678

(51) Int. Cl. H01L 33/48; H01L 33/62

(52) U.S. Cl. CPC H01L 33/483; H01L 33/62

(57) ABSTRACT

An Light-Emitting Diode illumination apparatus includes a light source unit which has a first housing storing a Light-Emitting Diode and in which a pair of contact point portions connected to the Light-Emitting Diode are exposed from the first housing; and a function unit which has a second housing storing the first housing and has a pair of contacted point portions provided in the second housing for supplying power to the Light-Emitting Diode connected to the pair of contact point portions, wherein the pair of contact point portions are provided with engagement protruding portions having different outline shapes, respectively, and the pair of contacted point portions are provided with engagement recessed portions into which the engagement protruding portions of the pair of contact point portions are insertable, respectively.

### CROSS REFERENCE TO RELATED APPLICATIONS

This application is a Continuation of PCT Application No. PCT/JP2014/055078, filed on Feb. 28, 2014, and claims the priority of Japanese Patent Application No. 2013-042678, filed on Mar. 5, 2013, the content of both of which is incorporated herein by reference.

### TECHNICAL FIELD

The present invention relates to a Light-Emitting Diode illumination apparatus.

### BACKGROUND ART

Conventionally, a Light-Emitting Diode illumination apparatus is known that includes a boat-shaped bulb or a wedge-based bulb as a light source unit having a first housing for storing a Light-Emitting Diode, and a function unit having a second housing for storing the first housing. In the light source unit of the Light-Emitting Diode illumination apparatus, a pair of contact point portions connected to the Light-Emitting Diode are provided to be exposed from the first housing. Further, in the second housing of the function unit, first lamp contact point portions, or second lamp contact point portions are provided as a pair of contacted point portions that are connected to the pair of contact point portions and supply power to the Light-Emitting Diode (e.g, refer to Patent Literature 1).

In the above-described Light-Emitting Diode illumination apparatus, the pair of first lamp contact point portions having a same hole-like shape and the pair of second lamp contact point portions having a same clamp-like shape are arranged at different places in the second housing so that the boat-shaped bulb and the wedge-based bulb that are different in type can be assembled into the function unit.

### CITATION LIST

### Patent Literature

Patent Literature 1: Japanese Patent Laid-Open Publication No. 2009-274675

### SUMMARY OF INVENTION

### Technical Problem

However, since, in the Light-Emitting Diode illumination apparatus described in the above-described patent literature 1, the pair of contact point portions have a same shape and, further, the pair of contacted point portions have a same shape, the light source unit may be inversely assembled into the function unit. If the light source unit is inversely assembled into the function unit erroneously, since the Light-Emitting Diode has polarity, the Light-Emitting Diode loses a function as the light source to cause a problem that the apparatus does not light on.

Therefore, the purpose of the present invention is to provide the Light-Emitting Diode illumination apparatus that can prevent the light source unit from being erroneously assembled into the function unit.

### Solution to Problem

An Light-Emitting Diode illumination apparatus of the present invention includes a light source unit which has a first housing storing a Light-Emitting Diode and in which a pair of contact point portions connected to the Light-Emitting Diode are exposed from the first housing; and a function unit which has a second housing storing the first housing and has a pair of contacted point portions provided in the second housing for supplying power to the Light-Emitting Diode connected to the pair of contact point portions, wherein the pair of contact point portions are provided with engagement protruding portions having different outline shapes, respectively, and the pair of contacted point portions are provided with engagement recessed portions into which the engagement protruding portions of the pair of contact point portions are insertable, respectively.

In the Light-Emitting Diode illumination apparatus of the present invention, at least one of the engagement protruding portions of the pair of contact point portions may be engaged with the engagement recessed portion in a rotational direction of the first housing in a state of being inserted into the engagement recessed portion.

In the Light-Emitting Diode illumination apparatus of the present invention, one engagement protruding portion has a cuboid projecting portion; and the engagement recessed portion into which one engagement protruding portion is inserted has an elongate hole portion into which the cuboid projecting portion is insertable.

### BRIEF DESCRIPTION OF DRAWINGS

FIG. 1 is a perspective view of a light source unit of a Light-Emitting Diode illumination apparatus according to an embodiment of the present invention.

FIG. 2 is an exploded perspective view of the light source unit of the Light-Emitting Diode illumination apparatus according to the embodiment of the present invention.

FIG. 3 is a perspective view of a function unit of the Light-Emitting Diode illumination apparatus according to the embodiment of the present invention.

FIG. 4 is an exploded perspective view of the function unit of the Light-Emitting Diode illumination apparatus according to the embodiment of the present invention.

FIG. 5A is a perspective view when a switch unit of the Light-Emitting Diode illumination apparatus is assembled according to the embodiment of the present invention.

FIG. 5B is a perspective view when the switch unit is assembled into a second housing of the Light-Emitting Diode illumination apparatus according to the embodiment of the present invention.

FIG. 6 is a perspective view when a bus bar, a terminal, and a switch cover are assembled into the second housing of the Light-Emitting Diode illumination apparatus according to the embodiment of the present invention.

FIG. 7 is a perspective view when a wire harness and a pressure-contact cover are assembled into the second housing of the Light-Emitting Diode illumination apparatus according to the embodiment of the present invention.

FIG. 8 is a perspective view when the light source unit is assembled into the function unit of the Light-Emitting Diode illumination apparatus according to the embodiment of the present invention.

FIG. 9 is a perspective view of the Light-Emitting Diode illumination apparatus according to the embodiment of the present invention.

FIG. 10 is a cross-sectional view taken along an X-X line illustrated in FIG. 9.

FIG. 11A is a cross-sectional view taken along a XIA-XIA line illustrated in FIG. 10.

FIG. 11B is a cross-sectional view taken along a XIB-XIB line illustrated in FIG. 10.

FIG. 12 is a perspective view of a light source unit of another example of the Light-Emitting Diode illumination apparatus according to the embodiment of the present invention.

### DESCRIPTION OF EMBODIMENTS

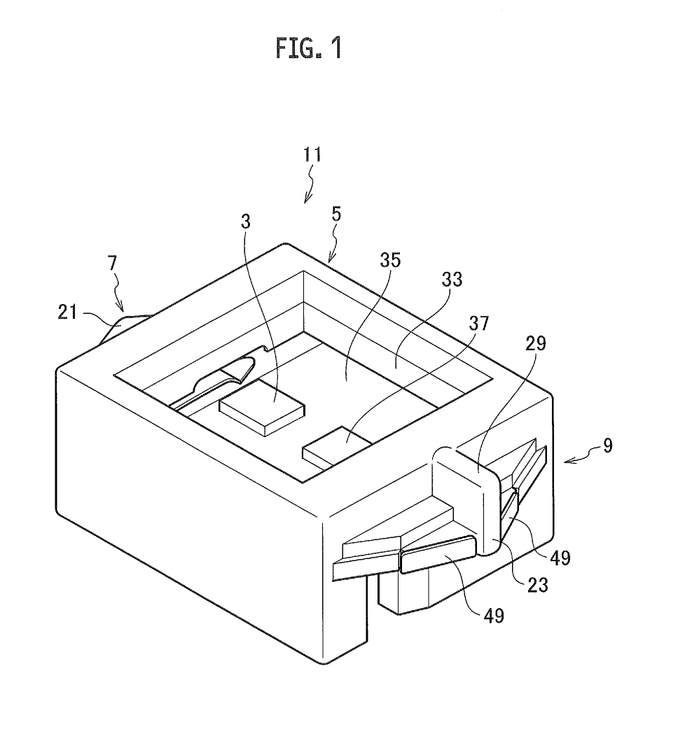

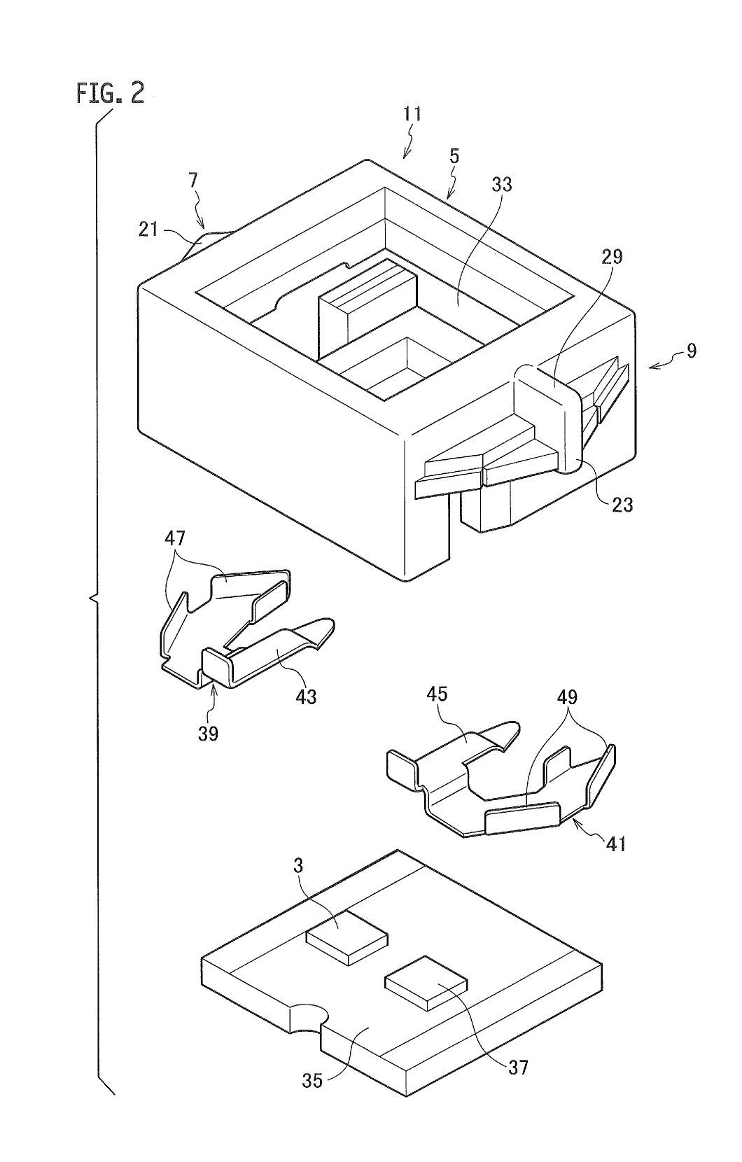

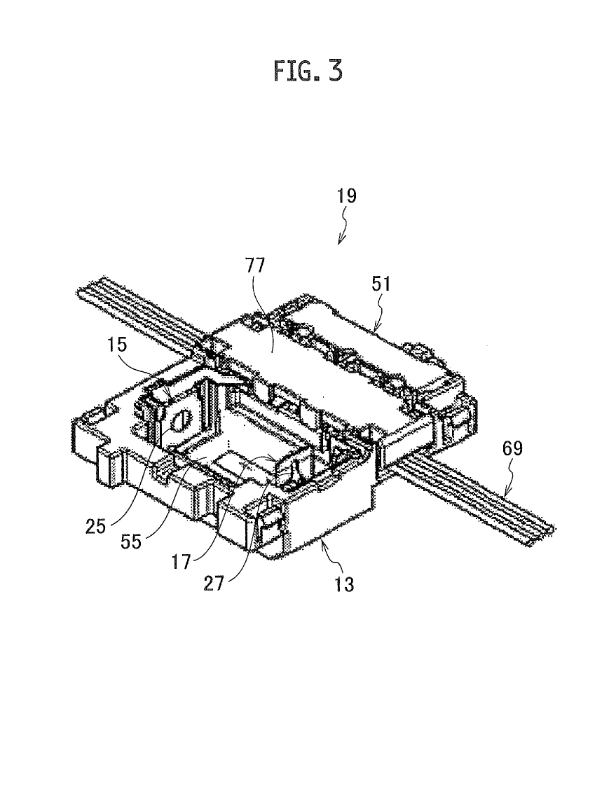

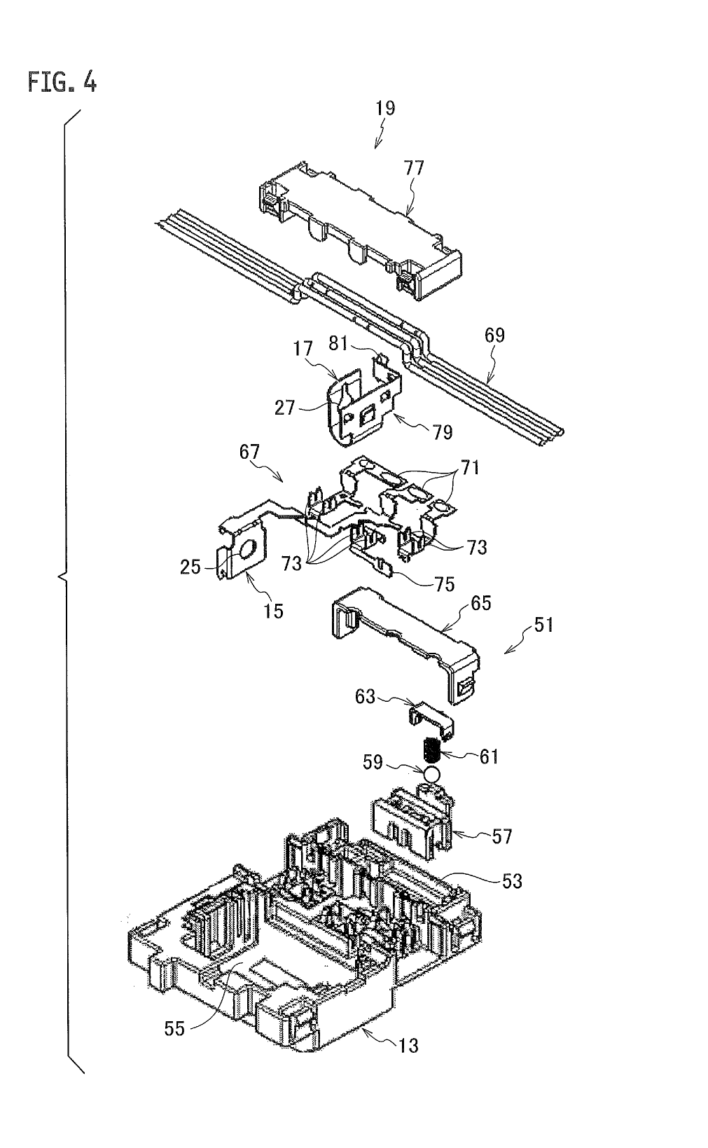

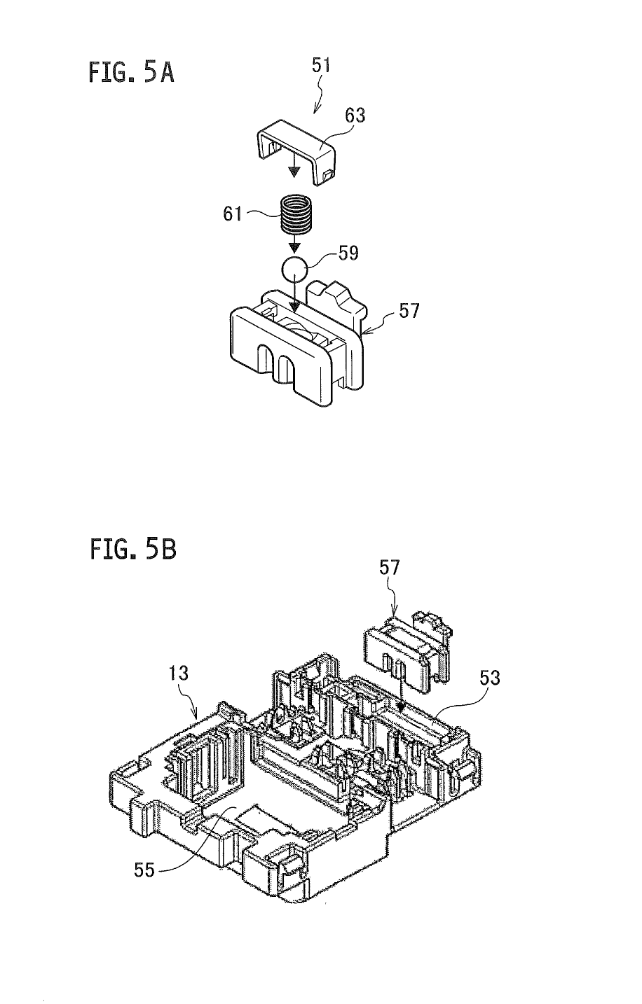

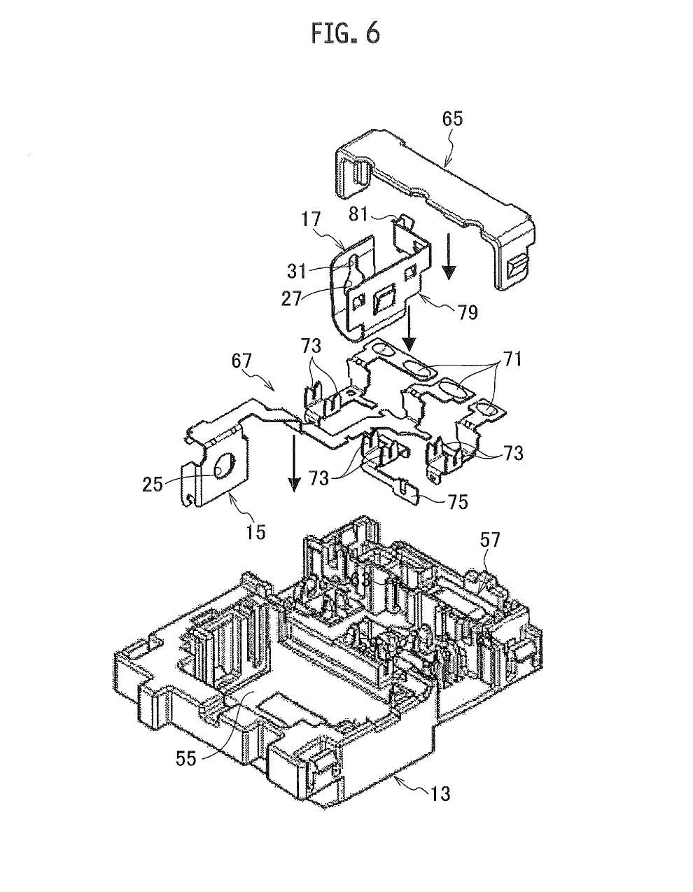

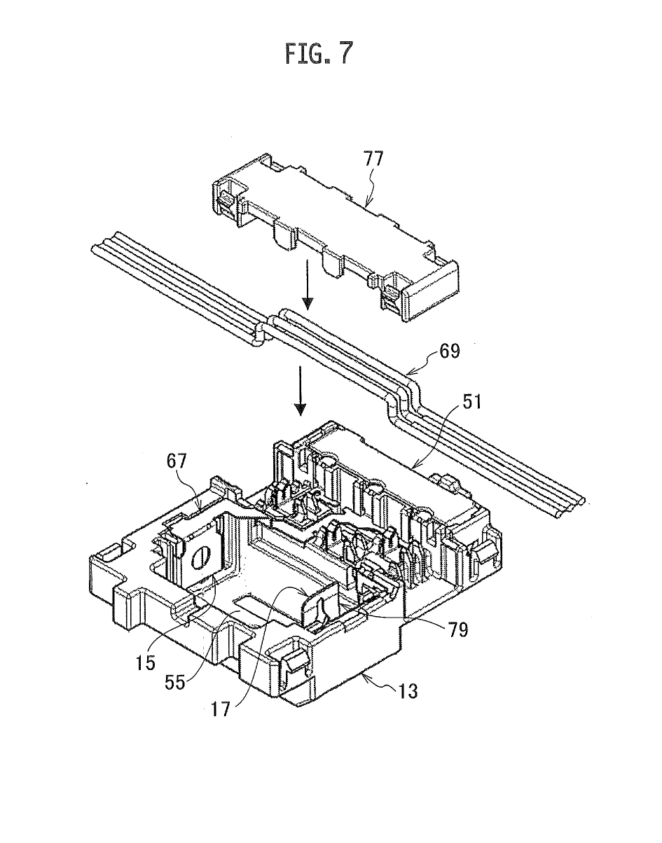

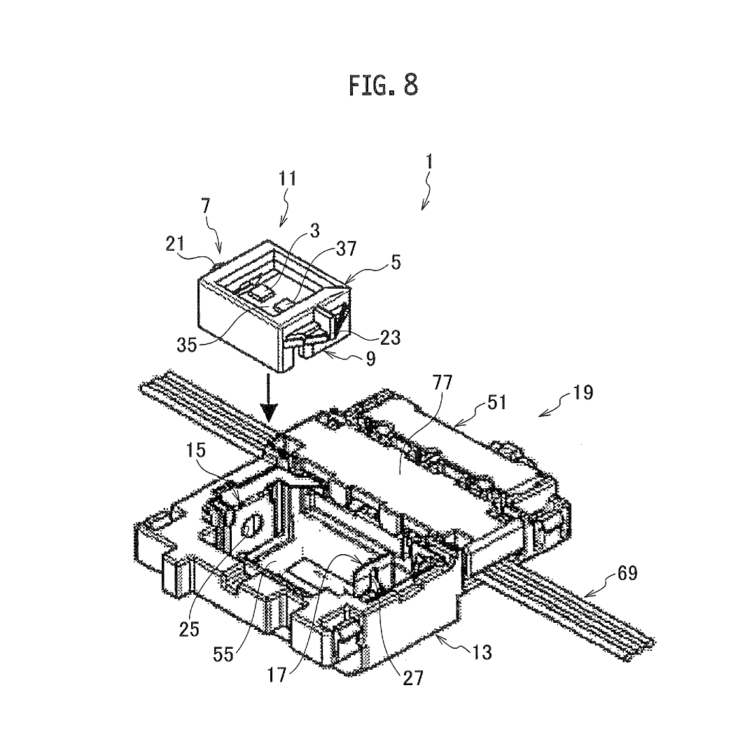

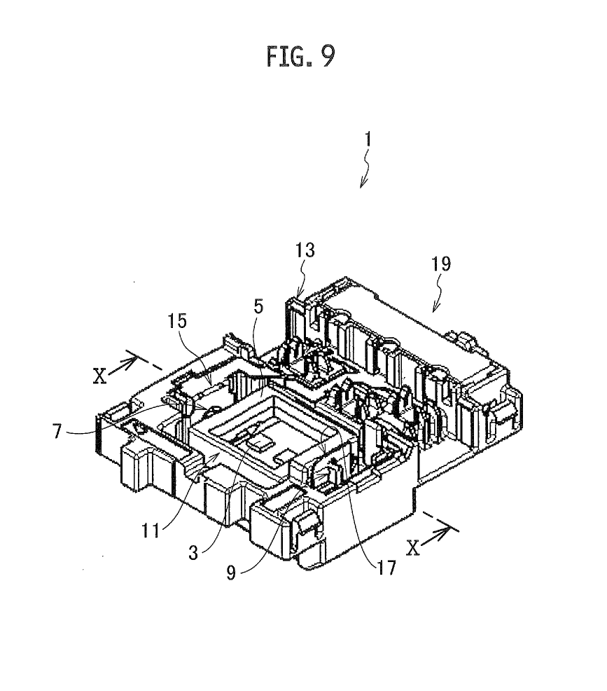

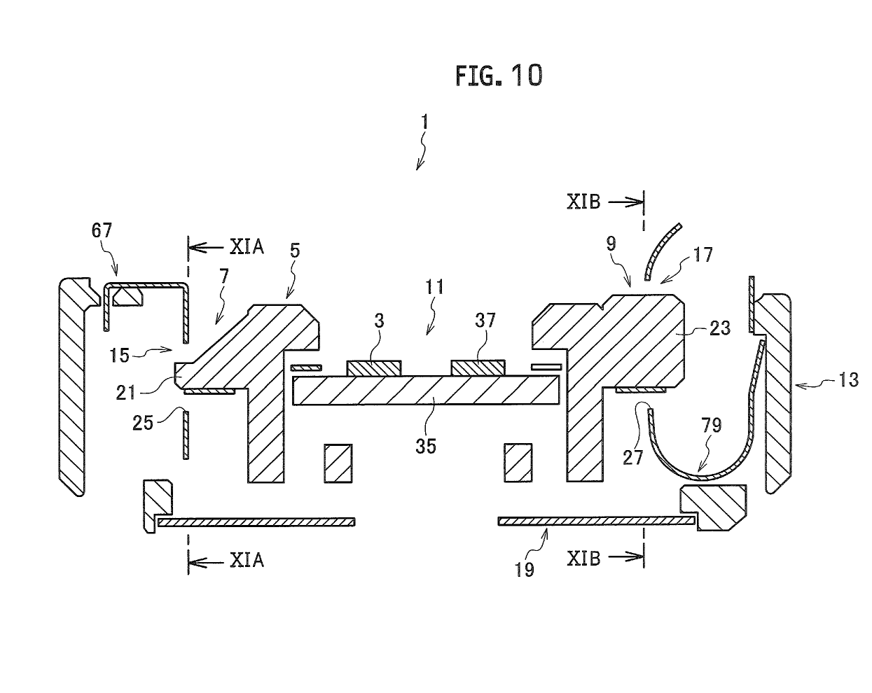

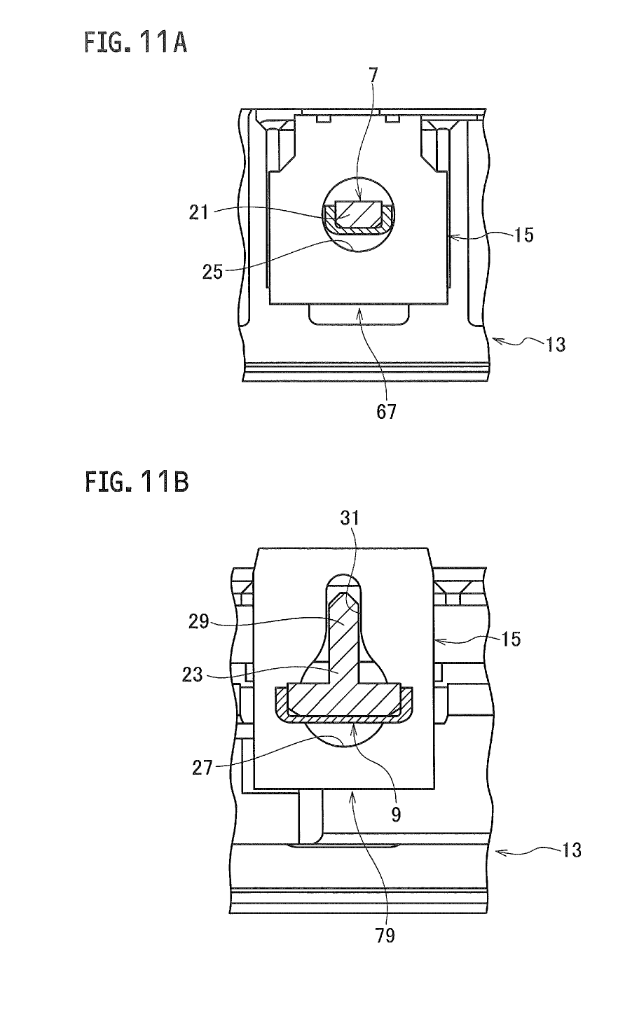

With reference to FIG. 1 to FIG. 12, a Light-Emitting Diode illumination apparatus according to an embodiment of the present invention will be described.

An Light-Emitting Diode illumination apparatus 1 according to the present embodiment includes a light source unit 11 which has a first housing 5 for storing a Light-Emitting Diode 3 and in which a pair of contact point portions 7, 9 connected to the Light-Emitting Diode 3 are exposed from the first housing 5, and a function unit 19 which has a second housing 13 for storing the first housing 5 and has a pair of contacted point portions 15, 17 provided in the second housing 13 for supplying power to the Light-Emitting Diode 3 connected to the pair of contact point portions 7, 9.

The pair of contact point portions 7, 9 are provided with engagement protruding portions 21, 23 having different outline shapes, respectively, and the pair of contacted point portions 15, 17 are provided with engagement recessed portions 25, 27 into which the engagement protruding portions 21, 23 of the pair of contact point portions 7, 9 are insertable, respectively.

Further, the engagement protruding portion 23 is engaged with the engagement recessed portion 27 in the rotational direction and the first housing 5 in a state of being inserted into the engagement recessed portion 27.

“With the engagement recessed portion 27 in the rotational direction” refers to a rotational direction about a rotational axis center of a line connecting the pair of contact point portions 7, 9 with each other. Or, it refers to a rotational direction about a rotational axis center in an insertion direction when the engagement protruding portion 23 is inserted into the engagement recessed portion 27.

Further, the engagement protruding portion 23 has a cuboid projecting portion 29, and the engagement recessed portion 27 into which the engagement protruding portion 23 is inserted has an elongate hole portion 31 into which an cuboid projecting portion 29 is insertable.

In a state where the engagement protruding portion 23 is inserted into the engagement recessed portion 27, since the first housing 5 is supported by the engagement recessed portion 27 via the engagement protruding portion 23, a movement in the above-described rotational direction is suppressed.

As illustrated in FIG. 1 to FIGS. 11A and 11B, the Light-Emitting Diode illumination apparatus 1 is provided between a vehicle body and a trim arranged on a ceiling in a vehicle compartment for example, and adopted to an illumination apparatus for lighting the vehicle compartment. The Light-Emitting Diode illumination apparatus 1 includes the light source unit 11 and the function unit 19.

The light source unit 11 includes the first housing 5, the Light-Emitting Diode 3, and the pair of contact point portions 7, 9. The first housing 5 is made of synthetic resin material, formed in a housing-like shape, and includes a storage unit 33 for storing the Light-Emitting Diode 3 and the like therein. In a state where the Light-Emitting Diode illumination apparatus 1 is arranged inside the vehicle compartment, the first housing 5 is arranged with its opening side facing an inside of the vehicle compartment via a light-guiding lens (not illustrated) or the like.

The Light-Emitting Diode 3 includes an electronic component having a function as a light source irradiating inside the vehicle compartment, and is mounted on a substrate 35 formed with a desired circuit. The Light-Emitting Diode 3 is stored in the storage unit 33 of the first housing 5 to connect the substrate 35 with a pair of bus bars 39, 41 after the Light-Emitting Diode 3 is mounted on the substrate 35 together with a resistor 37 as the electronic component.

The pair of bus bars 39, 41 are made of conductive material such as copper alloy, and include substrate connection portions 43, 45 and cap contact point portions 47, 49. In a state where the pair of bus bars 39, 41 are stored in the storage unit 33 of the first housing 5, the substrate connection portions 43, 45 are electrically connected to the substrate 35, and the cap contact point portions 47, 49 are exposed on both side surfaces of the first housing 5 to configure the pair of contact point positions 7, 9.

The pair of contact point positions 7, 9 are provided on the both side surfaces of the first housing 5, respectively, and the cap contact point portions 47, 49 of the pair of bus bars 39, 41 are arranged respectively on inclining surfaces that decline toward both sides with a summit at a central portion of a side surface. In a state where the light source unit 11 is assembled into the function unit 19, the pair of contact point portions 7, 9 are electrically connected to the pair of contacted point portions 15, 17 of the function unit 19.

The function unit 19 includes the second housing 13 and the pair of contacted point portions 15, 17. The second housing 13 is made of the synthetic resin material, formed in a housing-like shape, and fixed to a vehicle body side to be arranged in such a manner that the opening side of the second housing 13 is oriented toward the vehicle compartment. The second ho using 13 is provided with a switch storage unit 53 for mainly storing a switch unit 51, and a light source storage unit 55 for mainly storing the light source unit 11.

The switch unit 51 includes a slider 57 made of the synthetic resin material and stored in the switch storage unit 53 of the second housing 13, a ball 59 made of the conductive material such as copper alloy and stored in the slider 57, a spring 61, a contact 63, and a switch cover 65 made of the synthetic resin material and assembled into the second housing 13 to cover the slider 57.

In the switch unit 51, the slider 57 is stored in the switch storage unit 53 of the second housing 13 after the ball 59, the spring 61, and the contact 63 are stored in the slider 57, and then the switch cover 65 is assembled into the second housing 13 to block the slider 57. The switch unit 51 is connected to a wire harness 69 via a bus bar 67 assembled into the second housing 13.

The bus bar 67 is made of the conductive material such as copper alloy, and includes a plurality of switch contact point portions 71, a plurality of pressure-contact blades 73, a terminal connection portion 75, and one contacted point portion 15. In a state where the bus bar 67 is assembled into the second housing 13, the plurality of switch contact point portions 71 is connected to the switch unit 51 stored in the switch storage unit 53.

The plurality of pressure-contact blades 73 is erected in the second housing 13 in a state where the bus bar 67 is assembled into the second housing 13, and contacts the wire harness 69 including a plurality of coated wires connected to a power source or a device with pressure. The pressure-contact cover 77 is assembled into the second housing 13 so that the wire harness 69 is pressure-contacted with each of the plurality of pressure-contact blades 73 to electrically connect the bus bar 67 with the wire harness 69.

In the state where the bus bar 67 is assembled into the second housing 13, the terminal connection portion 75 is electrically connected to a bus bar connection portion 81 of a terminal 79 made of the conductive material such as copper alloy and stored in the second housing 13 together with the bus bar 67.

The one contacted point portion 15 is arranged in the light source storage unit 55 of the second housing 13 in a state where the bus bar 67 and the terminal 79 are assembled into the second housing 13, and further arranged to face the other contacted point portion 17 provided in the terminal 79. The contacted point portion 15 of the bus bar 67 and the contacted point portion 17 of the terminal 79 configure the pair of contacted point portions 15, 17 of the function unit 19.

The pair of contacted point portions 15, 17 are arranged in the light source storage unit 55 of the second housing 13 to face each other with a space for allowing the light source unit 11 to be arranged. The pair of contacted point portions 15, 17 are respectively connected to the pair of contact point portions 7, 9 of the light source unit 11 in a state where the light source unit 11 is stored in the light source storage unit 55 of the second housing 13, and thus the light source unit 11 and the function unit 19 are electrically connected with each other.

As described above, the light source unit 11 is assembled into the function unit 19 so that the power can be supplied from the function unit 19 to the light source unit 11. Further, the switch unit 51 of the function unit 19 can be intermittently operated to light on and off the Light-Emitting Diode 3 of the light source unit 11.

Since the Light-Emitting Diode 3 of the light source unit 11 has the polarity, if the pair of contact point portions 7, 9 of the light source unit 11 are inversely connected to the pair of contacted point portions 15, 17 of the function unit 19, the function of the Light-Emitting Diode 3 as the light source will be lost. Thus, the pair of contact point portions 7, 9 and the pair of contacted point portions 15, 17 adopt a prevention configuration of preventing the light source unit 11 from being erroneously assembled into the function unit 19.

The pair of contact point portions 7, 9 are provided with engagement protruding portions 21, 23 that have different outline shapes and are provided on the both side surfaces of the first housing 5. The engagement protruding portion 21 provided on the one contact point portion 7 is provided as protruding from the side surface of the first housing 5 in a rectangular columnar shape. The engagement protruding portion 23 provided on the other contact point portion 9 is provided as protruding from the side surface of the first housing 5 to form their cross section in a T-like shape, and has the cuboid projecting portion 29 extended in a height direction of the first housing 5.

In the state where the light source unit 11 is assembled into the function unit 19, the engagement protruding portions 21, 23 respectively provided on the pair of contact point portions 7, 9 are inserted into the engagement recessed portions 25, 27 provided in the pair of contacted point portions 15, 17, respectively.

The pair of contacted point portions 15, 17 are respectively provided with the engagement recessed portions 25, 27 having different shapes into which the engagement protruding portions 21, 23 are insertable. The engagement recessed portion 25 provided in the one contacted point portion 15 of the bus bar 67 is formed in a circular hole portion into which the engagement protruding portion 21 is insertable. The engagement recessed portion 27 provided in the other contacted point portion 17 of the terminal 79 is formed in a hole portion sequentially formed with a circular hole portion into which the engagement protruding portion 23 is insertable and the elongate hole portion 31 into which the cuboid projecting portion 29 is insertable.

As described above, the shapes of the engagement recessed portions 25, 27 provided in the pair of contacted point portions 15, 17 correspond to those of the engagement protruding portions 21, 23 provided on the pair of contact point portions 7, 9. Thereby, even when the light source unit 11 is tried to be inversely assembled into the function unit 19, the engagement protruding portion 23 provided on the other contact point portion 9 cannot be inserted into the engagement recessed portion 25 provided in the one contacted point portion 15, and thus the light source unit 11 cannot be assembled into the function unit 19.

As described above, the outline shapes of the engagement protruding portions 21, 23 provided on the pair of contact point portions 7, 9 are made different so that the shapes of the engagement recessed portions 25, 27 provided in the pair of contacted point portions 15, 17 correspond to the outline shapes of the engagement protruding portions 21, 23. Thereby, the light source unit 11 can be prevented from being erroneously assembled into the function unit 19, thus allowing the Light-Emitting Diode 3 to easily function as the light source.

Herein, in a state where the engagement protruding portion 23 provided on the contact point portion 9 is inserted into the engagement recessed portion 27 of the contacted point portion 17, facing surfaces of the cuboid projecting portion 29 and the elongate hole portion 31 of the engagement recessed portion 27 are engaged with each other in the rotational direction (rotational direction about the rotational axis center of the line connecting the pair of contact point portions 7, 9 with each other) of the first housing 5.

In the state where the light source unit 11 is assembled into the function unit 19, the cuboid projecting portion 29 is engaged with the elongate hole portion 31 to specify an irradiation direction of the Light-Emitting Diode 3 without rotation of the first housing 5.

As an assembly method of the Light-Emitting Diode illumination apparatus 1 configured as described above, first, the ball 59, the spring 61, and the contact 63 are assembled into the slider 57, and then, the slider 57 is stored in the switch storage unit 53 of the second housing 13.

Subsequently, the bus bar 67 and the terminal 79 are assembled into the second housing 13, and the switch cover 65 is assembled into the second housing 13. Subsequently, the wire harness 69 is arranged to position at the plurality of pressure-contact blades 73 of the bus bar 67, a pressure-contact cover 77 is assembled into the second housing 13, and the wire harness 69 is press-contacted with the plurality of pressure-contact blades 73.

The light source unit 11 including the first housing 5 into which each component is previously assembled is arranged in such a manner that the pair of contact point portions 7, 9 respectively correspond to the pair of contacted point portions 15, 17 of the function unit 19. The light source unit 11 arranged at a regular position is assembled into the light source storage unit 55 of the second housing 13, and then the assembly into the apparatus is completed.

In such a Light-Emitting Diode illumination apparatus 1, the engagement protruding portions 21, 23 having different outline shapes are provided on the pair of contact point portions 7, 9, and the engagement recessed portions 25, 27 into which the engagement protruding portions 21, 23 of the pair of contact point portions 7, 9 are insertable are provided in the pair of contacted point portions 15, 17, respectively. Therefore, even when the light source unit 11 is tried to be erroneously assembled into the function unit 19 inversely, the engagement protruding portions 21, 23 cannot be inserted into the engagement recessed portions 25, 27, and thus the light source unit 11 cannot be assembled into the function unit 19.

Therefore, in such a Light-Emitting Diode illumination apparatus 1, the light source unit 11 can be prevented from being erroneously assembled into the function unit 19, and the Light-Emitting Diode 3 does not lose the function as the light source to light on the apparatus.

Further, in the state where the engagement protruding portion 23 is inserted into the engagement recessed portion 27, the first housing 5 is supported by the engagement recessed portion 27 via the engagement protruding portion 23 so that the engagement protruding portion 23 is engaged with the engagement recessed portion 27 in the rotational direction of the first housing 5. Therefore, the first housing 5 does not rotate in the second housing 13 to specify the irradiation direction of the Light-Emitting Diode 3, thereby allowing light to be stably irradiated in a necessary direction.

Further, the engagement protruding portion 23 has the cuboid projecting portion 29, and the engagement recessed portion 27 into which the engagement protruding portion 23 is inserted has the elongate hole portion 31 into which the cuboid projecting portion 29 is insertable. Therefore, it is possible to specify the irradiation direction of the Light-Emitting Diode 3, while preventing rotation of the first housing 5 with a simple configuration.

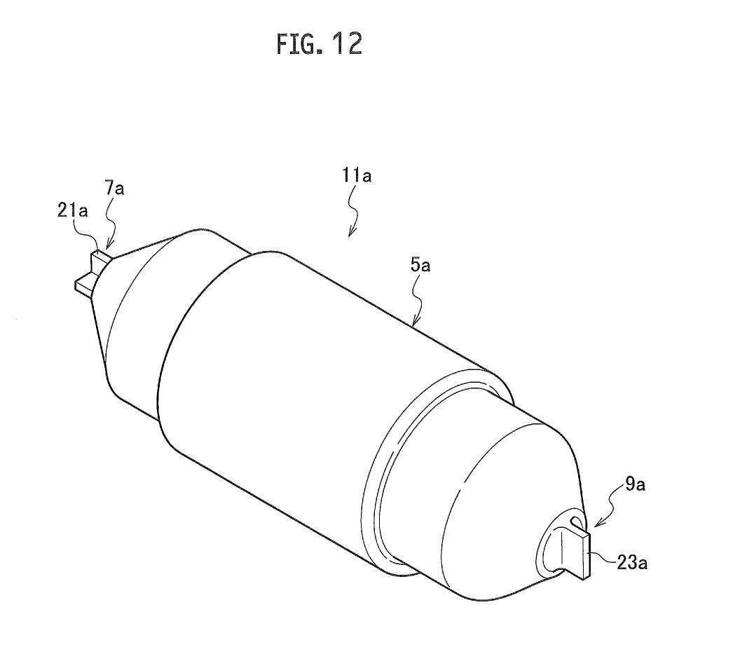

In the Light-Emitting Diode illumination apparatus 1 according to the present embodiment, the first housing 5 of the light source unit 11 does not store the Light-Emitting Diode 3 to cover it. However, for example, as illustrated in FIG. 12, in the light source unit 11a, a first housing 5a is formed of the conductive material in a cylindrical shape and a pair of contact point portions 7a, 9a to become the cap contact point portions may be provided at both sides of the first housing 5a.

In such a pair of contact point portions 7a, 9a in the light source unit 11a also, engagement protruding portions 21a, 23a having different outline shapes (e.g., one is formed in a “+” shape, and the other one is formed in a “−” shape) are provided to form the engagement recessed portions 25, 27 in the corresponding one pair of contacted point portions 15, 17 in shapes into which the engagement protruding portions 21a, 23a are insertable.

With the configuration as described above, even if the light source unit 11a is tried to be erroneously assembled into the function unit 19 inversely, the engagement protruding portions 21a, 23a cannot be inserted into the engagement recessed portions 25, 27, and thus the light source unit 11 a cannot be assembled into the function unit 19. In addition, the pair of contact point portions 7a, 9a are formed into the “+” shape and the “−” shape so that the first housing 5a does not rotate in the second housing 13 and can specify the irradiation direction of the Light-Emitting Diode 3, thereby allowing the light to stably irradiate in the necessary direction.

Further, the shapes of the pair of contact point portions may have any shapes as long as the outline shapes are different. In addition, it is preferable that at least one of the outline shapes of the pair of contact point portions has a shape for preventing rotation of the first housing.

The embodiments of the present invention are described as above, however, the embodiments are only examples described for easier understanding of the present invention. The present invention is not limited to the embodiments. Technical scope of the present invention is not limited to specific technical matters disclosed in the above-described embodiments, and includes various types of modifications, changes, and alternative techniques that can be easily obtained from the technical matters.

### INDUSTRIAL APPLICABILITY

According to the present invention, an effect can be obtained in which a Light-Emitting Diode illumination apparatus that can prevent a light source unit from being erroneously assembled into a function unit can be provided.

### REFERENCE SIGNS LIST

1 Light-Emitting Diode illumination apparatus

3 Light-Emitting Diode

5, 5a first housing

7, 9, 7a, 9a a pair of contact point portions

11, 11a light source unit

13 second housing

15, 17 a pair of contacted point portions

19 function unit

21, 23, 21a, 23a engagement protruding portion

25, 27 engagement recessed portion

29 cuboid projecting portion

31 elongate hole portion

1. An Light-Emitting Diode illumination apparatus, comprising:
a light source unit which has a first housing storing a Light-Emitting Diode and in which a pair of contact point portions connected to the Light-Emitting Diode are exposed from the first housing; and
a function unit which has a second housing storing the first housing and has a pair of contacted point portions provided in the second housing for supplying power to the Light-Emitting Diode connected to the pair of contact point portions, wherein
the pair of contact point portions are provided with engagement protruding portions having different outline shapes, respectively, and
the pair of contacted point portions are provided with engagement recessed portions into which the engagement protruding portions of the pair of contact point portions are insertable, respectively.

2. The Light-Emitting Diode illumination apparatus according to claim 1, wherein at least either one of the engagement protruding portions of the pair of contact point portions is engaged with the engagement recessed portion in a rotational direction of the first housing in a state of being inserted into the engagement recessed portion.

3. The Light-Emitting Diode illumination apparatus according to claim 2, wherein the one engagement protruding portion has a cuboid projecting portion; and
the engagement recessed portion into which the one engagement protruding portion is inserted has an elongate hole portion into which the cuboid projecting portion is insertable.
